(19) United States
(12) Patent Application Publication
(10) Pub. No.: US 2012/0034756 A1
(43) Pub. Date: Feb. 9, 2012

(54) Method of Forming a Deep Trench Isolation Structure Using a Planarized Hard Mask

(76) Inventors: Taehun Kwon, Scarborough, ME (US); Akshey Sehgal, Scarborough, ME (US); Donald Robertson Getchell, York, ME (US); Patrick McCarthy, Hollis Center, ME (US); Rodney L. Hill, Buxton, ME (US); Yaojian Leng, Scarborough, ME (US)

(21) Appl. No.: 12/851,996

(22) Filed: Aug. 6, 2010

(51) Int. Cl. H01L 21/762

(52) U.S. Cl. 438/424; 257/E21.546

(57) ABSTRACT

A number of deep trench openings are formed in a semiconductor wafer to have substantially equal depths and no oxide undercut by forming a number of shallow trench openings, forming a mask structure in the shallow trench openings where the mask structure has a substantially planar top surface, forming a number of mask openings in the mask structure, and etching the semiconductor wafer through the mask openings to form the deep trench openings.

### BACKGROUND OF THE INVENTION

1. Field of the Invention.

The present invention relates to a method of forming a deep trench isolation structure and, more particularly, to a method of forming a deep trench isolation structure using a planarized hard mask.

2. Description of the Related Art.

A deep trench isolation structure is a well-known semiconductor structure that includes a shallow non-conductive region and a deep non-conductive region that is narrower than the shallow non-conductive region. The shallow non-conductive region extends down a short distance into a semiconductor wafer from the top surface of the wafer, while the deep non-conductive region extends down a much longer distance into the wafer from the bottom surface of the shallow non-conductive region. Deep trench isolation structures are widely utilized to isolate laterally adjacent devices, such as transistors, resistors, and capacitors, due to the small surface area and low parasitic capacitance of the isolation structures.

FIGS. 1A-1H show cross-sectional views that illustrate a prior-art method 100 of forming deep trench isolation structures. As shown in FIG. 1A, method 100, which utilizes a conventionally-formed semiconductor wafer 110, begins by depositing an oxide layer 112 on wafer 110, followed by the deposition of a nitride layer 114 on oxide layer 112.

Next, a patterned photoresist layer 116 is formed on the top surface of nitride layer 114. Patterned photoresist layer 116 is formed in a conventional manner, which includes depositing a layer of photoresist, projecting a light through a patterned black/clear glass plate known as a mask to form a patterned image on the layer of photoresist, and removing the imaged photoresist regions, which were softened by exposure to the light.

As shown in FIG. 1B, after patterned photoresist layer 116 has been formed, the exposed regions of nitride layer 114 and the underlying regions of oxide layer 112 and wafer 110 are etched to form a number of shallow trench openings 120, which include a narrow shallow trench opening 120A and a wide shallow trench opening 120B. After the shallow trench openings 120 have been formed, patterned photoresist layer 116 is removed.

As shown in FIG. 1C, following the removal of patterned photoresist layer 116, a hard mask layer 122 is deposited on the exposed regions of nitride layer 114, oxide layer 112, and wafer 110 to fill the shallow trench openings 120. As a result of shallow trench opening 120A being narrower than shallow trench opening 120B, the portion of hard mask layer 122 that lies in narrow shallow trench opening 120A is thicker than the portion of hard mask layer 122 that lies in wide shallow trench opening 120B. Hard mask layer 122 can be implemented with, for example, a layer of oxide.

Following this, as shown in FIG. 1D, a patterned photoresist layer 124 is formed on the top surface of hard mask layer 122 in a conventional manner. Patterned photoresist layer 124, in turn, has a number of photoresist openings 126 that expose the top surface of hard mask layer 122. (Only two openings 126 are shown for clarity.)

However, because the portion of hard mask layer 122 that lies in narrow shallow trench opening 120A is thicker than the portion of hard mask layer 122 that lies in wide shallow trench opening 120B, the layer of photoresist deposited on hard mask layer 122 is deeper over wide shallow trench opening 120B than it is over narrow shallow trench opening 120A.

Thus, when light is projected onto the layer of photoresist, the layer of photoresist over narrow shallow trench opening 120A is significantly overexposed when compared to the layer of photoresist over wide shallow trench opening 120B. As a result, when the softened photoresist regions exposed by the light are removed to form the openings 126 in the photoresist layer, the width WX of the opening 126 that lies over narrow shallow trench opening 120A is bigger than the width WY of the opening 126 that lies over wide shallow trench opening 120B.

As shown in FIG. 1E, once patterned photoresist layer 124 has been formed, the exposed regions of hard mask layer 122 are etched to form a number of mask openings 130 that expose the top surface of wafer 110. Since the width WX of the opening 126 that lies over narrow shallow trench opening 120A is bigger than the width WY of the opening 126 that lies over wide shallow trench opening 120B, the width WX of the opening 130 that lies over narrow shallow trench opening 120A is also bigger than the width WY of the opening 130 that lies over wide shallow trench opening 120B. After the mask openings 130 have been formed, patterned photoresist layer 124 is removed in a conventional manner.

After patterned photoresist layer 124 has been removed, as shown in FIG. 1F, wafer 110 is etched in a conventional manner to form a number of deep trench openings 132, which include a first deep trench opening 132A that extends down from the bottom surface of narrow shallow trench opening 120A, and a second deep trench opening 132B that extends down from the bottom surface of wide shallow trench opening 120B.

As further shown in FIG. 1F, at the end of the etch, the deep trench openings 132A and 132B have different depths. The different depths, in turn, result from the different widths WX and WY of the openings 130 and the different thicknesses of hard mask layer 122 over narrow shallow trench opening 120A and wide shallow trench opening 120B.

The wider opening WX and the thicker hard mask layer 122 over narrow shallow trench opening 120A slow down the deep trench etch over narrow shallow trench opening 120A which, in turn, causes second deep trench opening 132B to be deeper than first deep trench opening 132A. Thus, the different widths of the openings 130 and the different thicknesses of hard mask layer 122 combine to give a net silicon etch rate and trench depth that is highly variable depending on the widths of the shallow trench openings 120.

As shown in FIG. 1G, after the deep trench openings 132 have been formed, hard mask layer 122 is removed with a wet etch in a conventional manner. Hard mask layer 122 is overetched to ensure that hard mask layer 122 is completely removed. The overetch of hard mask layer 122 also etches away some of oxide layer 112 which, in turn, forms an oxide undercut 134.

Next, as shown in FIG. 1H, following the removal of hard mask layer 122, an insulation material is deposited on the exposed regions of nitride layer 114, oxide layer 112, and wafer 110 to fill up the shallow and deep trench openings 120 and 132, and then planarized to form a number of deep trench isolation structures 140, which include deep trench isolation structures 140A and 140B.

One of the problems with method 100 is that method 100 can produce deep trench openings 132 which have different depths as illustrated in FIG. 1F. The different depths, in turn, can lead to yield issues when a deep trench opening 132 has an insufficient depth to provide the required isolation, which is determined by the maximum operating voltages of the laterally adjacent devices.

Another problem with prior-art method 100 is that the oxide undercut 134 that results from the overetch of hard mask layer 122 leads to sub-threshold leakage currents in CMOS transistors. Thus, there is a need for a method that forms deep trench isolation structures with substantially equal trench depths, and prevents the oxide undercut that results from the overetch of the hard mask layer.

### BRIEF DESCRIPTION OF THE DRAWINGS

FIGS. 1A-1H are cross-sectional views illustrating a prior-art method 100 of forming a number of deep trench isolation structures.

FIGS. 2A-2I are views illustrating an example of a method 200 of forming deep trench isolation structures in accordance with the present invention.

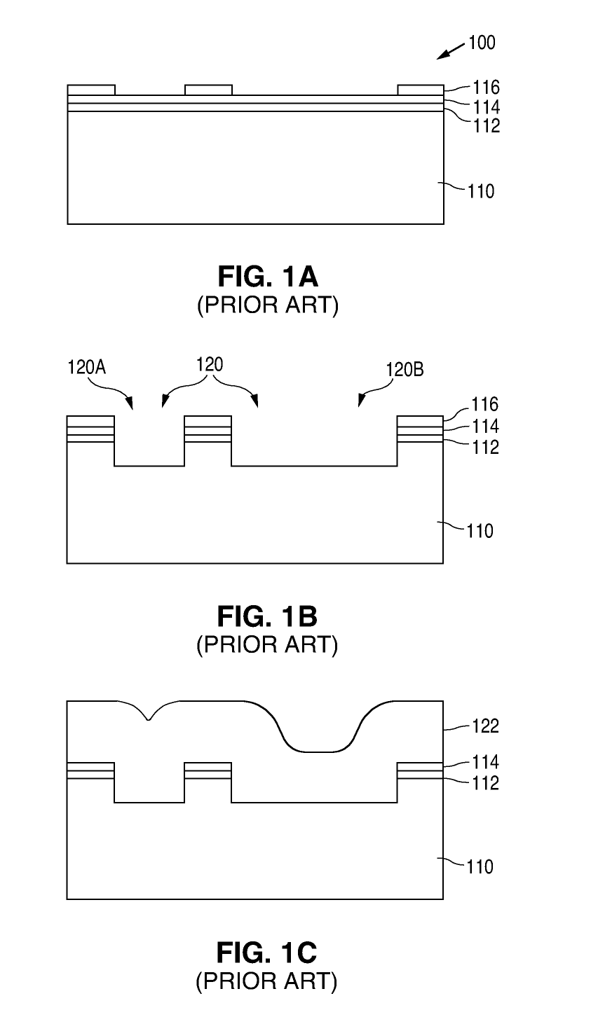

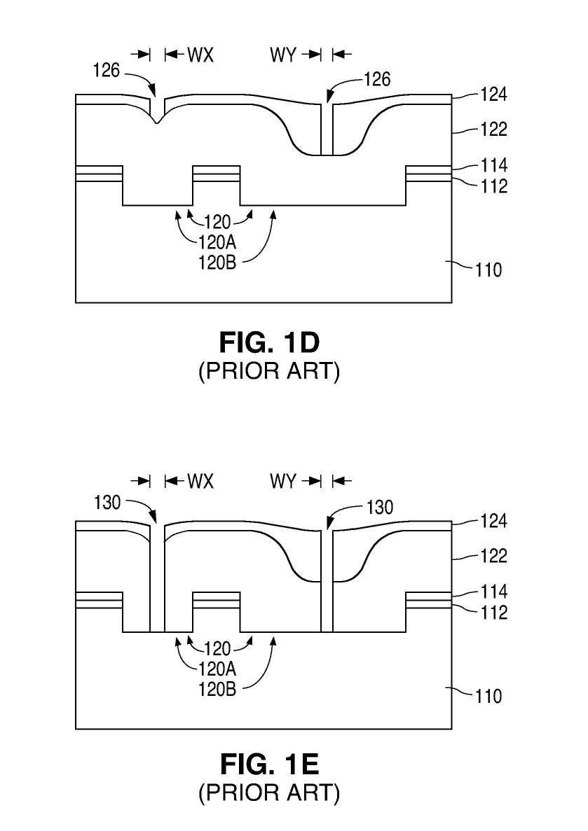

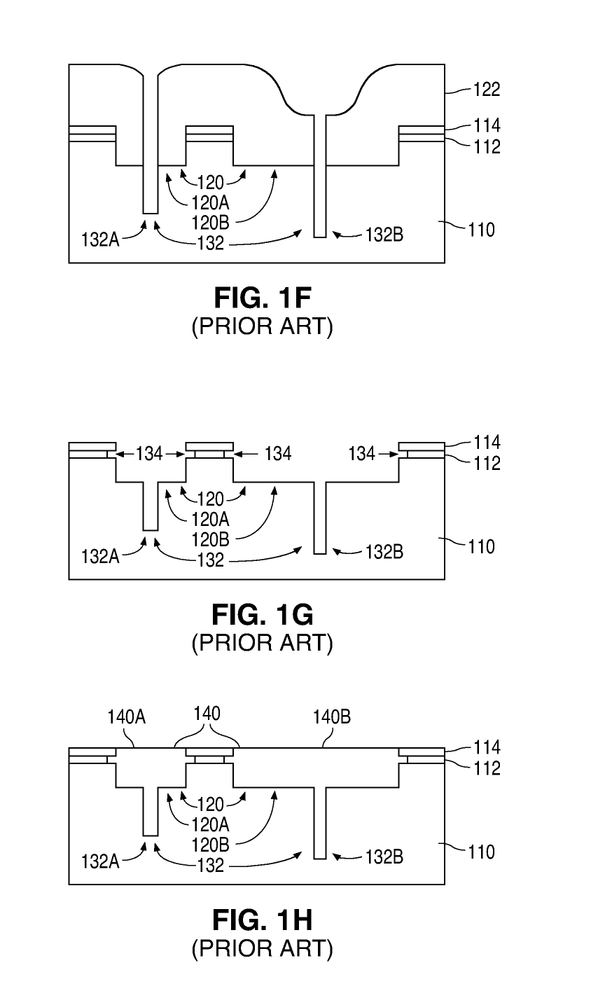

### DETAILED DESCRIPTION OF THE INVENTION

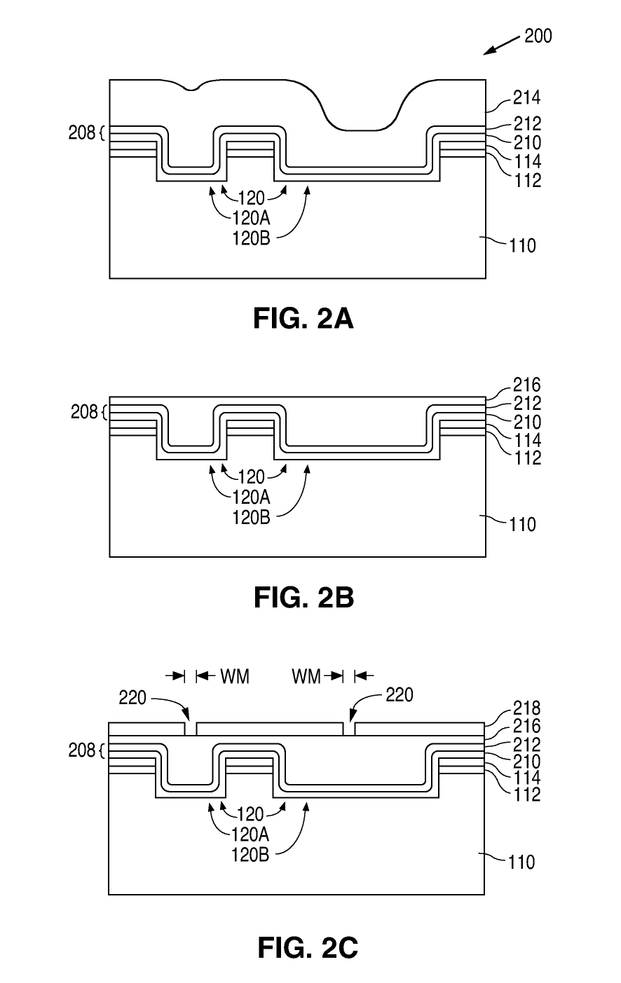

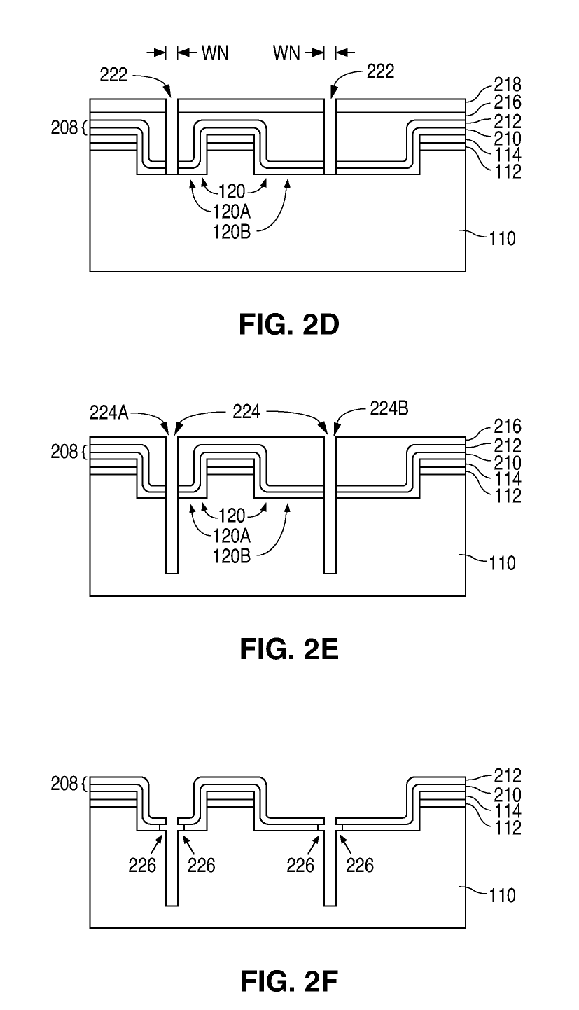

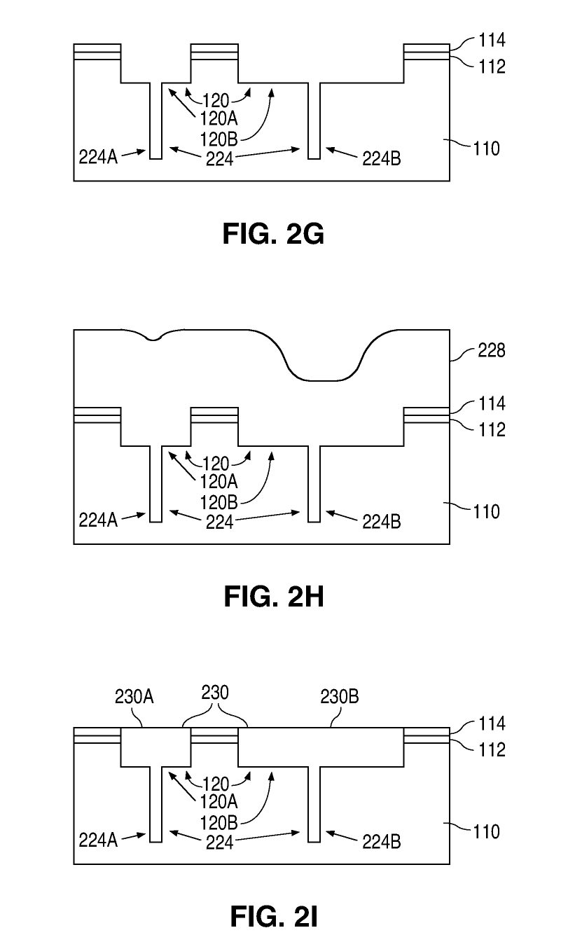

FIGS. 2A-2I show views that illustrate an example of a method 200 of forming deep trench isolation structures in accordance with the present invention. Method 200 is the same as method 100 up through the formation of the shallow trench openings 120 and, as a result, utilizes the same reference numerals to designate the structures which are common to both methods.

As shown in FIG. 2A, method 200 first differs from method 100 in that method 200 forms a sacrificial structure 208 over wafer 110 instead of forming hard mask layer 122. In the present example, sacrificial structure 208 is formed by depositing an oxide layer 210 on the exposed regions of nitride layer 114, oxide layer 112, and wafer 110 to line the shallow trench openings 120. Following this, a nitride layer 212 is deposited on oxide layer 210. Oxide layer 210 and nitride layer 212 are formed in a conventional manner.

Once sacrificial structure 208 has been formed, a hard mask layer 214 is deposited on sacrificial structure 208 so that the lowest portion of hard mask layer 214 lies above the highest portion of sacrificial structure 208. In the present example, hard mask layer 214 is deposited on nitride layer 212 so that the lowest portion of hard mask layer 214 lies above the highest portion of nitride layer 212. Hard mask layer 214, which is formed in a conventional manner, can be implemented with, for example, a layer of oxide.

As shown in FIG. 2B, after hard mask layer 214 has been deposited, hard mask layer 214 is planarized in a conventional manner, such as with chemical-mechanical polishing, to form a planarized hard mask 216. Following this, as shown in FIG. 2C, a patterned photoresist layer 218 is formed on the top surface of planarized hard mask 216 in a conventional manner. Patterned photoresist layer 218, in turn, has a number of photoresist openings 220 that expose the top surface of planarized hard mask 216. (Only two openings 220 are shown for clarity.)

In accordance with the present invention, the widths WM of the photoresist openings 220 in patterned photoresist layer 218, which are the critical dimensions, are substantially identical. This is because the thickness of patterned photoresist layer 218 is substantially uniform, being formed on the substantially planar surface of planarized hard mask 216.

As shown in FIG. 2D, once patterned photoresist layer 218 has been formed, the exposed regions of planarized hard mask 216 and the underlying regions of sacrificial layer 208 (nitride layer 212 and oxide layer 210 in the present example) are etched to form a number of mask openings 222 that expose the top surface of wafer 110. Since the widths WM of the photoresist openings 220 are substantially identical, the widths WN of the mask openings 222 are also substantially identical. After the mask openings 222 have been formed, patterned photoresist layer 218 is removed in a conventional manner.

After patterned photoresist layer 218 has been removed, as shown in FIG. 2E, wafer 110 is etched in a conventional manner to form a number of deep trench openings 224, which include a first deep trench opening 224A that extends down from the bottom surface of narrow shallow trench opening 120A, and a second deep trench opening 224B that extends down from the bottom surface of wide shallow trench opening 120B.

In accordance with the present invention, the deep trench openings 224A and 224B have substantially equal depths. The substantially equal depths result from the substantially equal widths WN of the mask openings 222 in planarized hard mask 216 which, in turn, result from the substantially equal widths WM of the openings 220 in patterned photoresist layer 218. Thus, even though the shallow trench openings 120A and 120B have different widths, the present invention ensures that the deep trench openings 224 have substantially equal depths.

As shown in FIG. 2F, after the deep trench openings 224 have been formed, planarized hard mask 216 is removed with a wet etch in a conventional manner. Planarized hard mask 216 is overetched to ensure that planarized hard mask 216 is completely removed. In the present example, the overetch of planarized hard mask 216 etches away some of oxide layer 210 which, in turn, forms an oxide undercut 226.

In accordance with the present invention, although the overetch of planarized hard mask 216 etches away some of oxide layer 210, thereby forming oxide undercut 226, the overetch of planarized hard mask 216 does not etch away any of oxide layer 112 because oxide layer 112 is protected by sacrificial structure 208 (nitride layer 212 and oxide layer 210 in the present example). As a result, the present invention prevents the formation of oxide undercut 134.

Next, as shown in FIG. 2G, following the removal of planarized hard mask 216, sacrificial structure 208 is removed in a conventional manner. In the present example, nitride layer 212 is removed in a conventional manner, followed by the conventional removal of oxide layer 210. After this, as shown in FIG. 2H, an insulation material 228 is deposited on the exposed regions of nitride layer 114, oxide layer 112, and wafer 110 to fill up the shallow and deep trench openings 120 and 224. Following this, as shown in FIG. 21, insulation material 228 is then planarized to form a number of deep trench isolation structures 230, which include deep trench isolation structures 230A and 230B.

Thus, a method of forming deep trench isolation structures has been described where a number of deep trench openings are formed to have substantially equal depths, regardless of whether the deep trench openings are formed in the bottom surfaces of narrow or wide shallow trench openings. As a result, the present invention improves yield by ensuring that the required isolation between adjacent devices is present.

In addition, since the method of the present invention eliminates the oxide undercut 134 of oxide layer 112 that results from the overetch of hard mask layer 122, the present invention also eliminates the CMOS sub-threshold leakage currents that result from the oxide undercut 134 of oxide layer 112.

It should be understood that the above descriptions are examples of the present invention, and that various alternatives of the invention described herein may be employed in practicing the invention. For example, although the present example is based on a positive resist approach, a negative resist approach can alternately be used. Thus, it is intended that the following claims define the scope of the invention and that structures and methods within the scope of these claims and their equivalents be covered thereby.

What is claimed is:

1. A method of forming a semiconductor structure comprising:
forming a shallow trench opening in a semiconductor wafer;
forming a mask structure that touches the semiconductor wafer and fills up the shallow trench opening, the mask structure having a substantially planar top surface;
forming a mask opening in the mask structure to expose the semiconductor wafer; and
etching the semiconductor wafer through the mask opening to form a deep trench opening.

2. The method of claim 1 wherein forming the mask structure includes:
forming a sacrificial structure that touches the semiconductor wafer and lines the shallow trench opening;
forming a hard mask layer that touches the sacrificial structure so that a lowest portion of the hard mask layer lies above a highest portion of the sacrificial structure; and
planarizing the hard mask layer to form a planarized hard mask.

3. The method of claim 2 wherein forming the mask opening includes selectively etching the planarized hard mask and the sacrificial structure to expose the semiconductor wafer.

4. The method of claim 2 wherein forming the mask opening includes:
forming a patterned photoresist layer on the planarized hard mask;
etching the planarized hard mask and the sacrificial structure to expose the semiconductor wafer; and
removing the patterned photoresist layer.

5. The method of claim 4 wherein the patterned photoresist layer is removed before the semiconductor wafer is etched to form the deep trench opening.

6. The method of claim 3 wherein forming the sacrificial structure includes:
forming a layer of oxide to touch the semiconductor wafer; and
forming a layer of nitride to touch the layer of oxide.

7. The method of claim 6 wherein the layer of oxide lines the shallow trench opening.

8. The method of claim 3 and further comprising:
removing the planarized hard mask after the semiconductor wafer has been etched to form the deep trench opening; and
removing the sacrificial structure after the planarized hard mask has been removed.

9. The method of claim 8 and further comprising forming an isolation structure in the deep trench opening and the shallow trench opening after the sacrificial structure has been removed.

10. The method of claim 9 wherein forming the isolation structure includes:
filling the deep trench opening and the shallow trench opening with an insulation material; and
planarizing the insulation material to form the isolation structure.

11. The method of claim 1 and further comprising removing the mask structure after the semiconductor wafer has been etched to form the deep trench opening.

12. The method of claim 11 and further comprising forming an isolation structure in the deep trench opening and the shallow trench opening after the mask structure has been removed.

13. The method of claim 12 wherein forming the isolation structure includes:
filling the deep trench opening and the shallow trench opening with an insulation material; and
planarizing the insulation material to form the isolation structure.

14. The method of claim 1 wherein forming the shallow trench opening includes:
forming a layer of oxide that touches the semiconductor wafer;
forming a layer of nitride that touches the layer of oxide; and
etching an opening in the layer of nitride, the layer of oxide, and the semiconductor wafer to form the shallow trench opening.

15. The method of claim 14 wherein the mask structure touches the layer of nitride.
